(19) United States
(12) Patent Application Publication
(10) Pub. No.: US 2012/0104384 A1
(43) Pub. Date: May 3, 2012

(54) THIN-FILM TRANSISTOR AND METHOD FOR MANUFACTURING THE SAME

(76) Inventors: Young-Joo CHOI, Gyeonggi-do (KR); Jae-Won SONG, Seoul (KR); Xun ZHU, Gyeonggi-do (KR); Sang-Wan JIN, Seoul (KR); Woo-Geun LEE, Gyeonggi-do (KR)

(21) Appl. No.: 13/193,459

(22) Filed: Jul. 28, 2011

(30) Foreign Application Priority Data
Oct. 29, 2010 (KR) 2010-0106556

(51) Int. Cl. H01L 29/786; H01L 21/44

(52) U.S. Cl. 257/43; 438/104; 257/E29.296; 257/E21.476

(57) ABSTRACT

A thin-film transistor (TFT) includes a gate electrode, an oxide semiconductor pattern, a source electrode, a drain electrode and an etch stopper. The gate electrode is formed on a substrate. The oxide semiconductor pattern is disposed in an area overlapping with the gate electrode. The source electrode is partially disposed on the oxide semiconductor pattern. The drain electrode is spaced apart from the source electrode, faces the source electrode, and is partially disposed on the oxide semiconductor pattern. The etch stopper has first and second end portions. The first end portion is disposed between the oxide semiconductor pattern and the source electrode, and the second end portion is disposed between the oxide semiconductor pattern and the drain electrode. A sum of first and second overlapping length is between about 30% and about 99% of a total length of the etch stopper.

### PRIORITY STATEMENT

This application claims priority under 35 U.S.C. §119 to Korean Patent Application No. 10-2010-0106556, filed on Oct. 29, 2010 in the Korean Intellectual Property Office (KIPO), the contents of which are herein incorporated by reference in their entirety.

### BACKGROUND OF THE INVENTION

1. Field of the Invention

A thin-film transistor (TFT) and a method for manufacturing the TFT is provided. More particularly, a TFT having an oxide semiconductor and a method for manufacturing the TFT are provided.

2. Description of the Related Art

Generally, thin-film transistors (TFT) may be classified into amorphous silicon (a-Si) TFTs, poly silicon (p-Si) TFTs, oxide semiconductor TFTs and so on, according to the material used for the semiconductor pattern. Oxide semiconductor TFTs have better electrical characteristics than other types of TFTs due to better reliability on a large-sized substrate at a low temperature, and higher electrical charge mobility.

An oxide semiconductor TFT may also include an etch stopper to protect the semiconductor pattern when the source and drain electrodes are formed. When an oxide semiconductor TFT includes an etch stopper, the etch stopper is formed on the semiconductor pattern of the TFT such that a first end portion of the etch stopper is disposed between the semiconductor pattern and the source electrode, and a second end portion of the etch stopper is formed between the semiconductor pattern and the drain electrode.

Generally, photolighography is used to pattern the elements of the TFT, such as the gate electrode, the semiconductor patter and so on. In photolithography, a mask is aligned on top of a substrate, which has a photoresist that is formed on a thin-film layer that is to be patterned. The alignment between the mask and the substrate is very important to ensure that the patterns are accurately positioned. However, an overlay misalignment between the mask and the substrate may occur at during manufacturing. Such an overlay misalignment may decrease the electrical characteristics of the TFT.

For example, when the etch stopper of the oxide semiconductor TFT is not properly aligned with the source and drain electrodes, an electrical field between one of the source and drain electrodes having a lager overlapping area with the etch stopper and the semiconductor pattern is easily generated. As a result, a channel may be formed in the etch stopper, which is an insulator, and therefore the misalignment may cause a change in the current-voltage characteristics of the oxide semiconductor TFT and may cause RC delay.

### SUMMARY OF THE INVENTION

A thin-film transistor (TFT) having a structure capable of minimizing a change of electric characteristics due to misalignment between an etch stopper and source and drain electrodes is provided.

A method for manufacturing the TFT is also provided.

In one aspect, the TFT includes a gate electrode, an oxide semiconductor pattern, a source electrode, a drain electrode and an etch stopper. The gate electrode is formed on a substrate. The oxide semiconductor pattern is disposed in an area overlapping with the gate electrode. The source electrode is partially disposed on the oxide semiconductor pattern. The drain electrode is spaced apart from the source electrode, faces the source electrode and is partially disposed on the oxide semiconductor pattern. The etch stopper has first and second end portions. The first end portion is disposed between the oxide semiconductor pattern and the source electrode. The second end portion is disposed between the oxide semiconductor pattern and the drain electrode. A first overlapping length is defined as a length along a direction from the source electrode toward the drain electrode in an area where the source electrode and the first end portion overlap with each other. The second overlapping length is defined as a length along a direction from the drain electrode toward the source electrode in an area where the drain electrode and the second end portion overlap with each other. The sum of first and second overlapping length is between about 30% and about 99% of a total length of the etch stopper between an outer edge of the first end portion and an outer edge of the second end portion.

The sum of the first and second overlapping length may be more than about 4 μm and not more than 10 μm.

The etch stopper may include first and second layers. The first layer directly contacts the oxide semiconductor pattern. The second layer may be formed on the first layer, directly contact the source and drain electrodes, and have a material different from the first layer.

In another aspect, the TFT includes a gate electrode, an oxide semiconductor pattern, an etch stopper and source and drain electrodes. The gate electrode is formed on a substrate. The oxide semiconductor pattern is disposed in an area overlapping with the gate electrode. The etch stopper includes first and second layers. The first layer is formed on the oxide semiconductor pattern. The second layer is formed on the first layer and has a material different from the first layer. The source and drain electrodes respectively overlap with both end portions of the etch stopper.

The first layer may have a thickness between about 300 Å and about 1000 Å, and the second layer may have a thickness between about 300 Å and about 2000 Å.

In a method for manufacturing a TFT, a gate electrode is formed on a substrate. An oxide semiconductor pattern is formed on the substrate having the gate electrode. An etch stopper is formed on the substrate having the oxide semiconductor pattern. Source and drain electrodes are formed on the substrate having the etch stopper. The source and drain electrodes are spaced apart from each other. A first overlapping length is defined as a length along a direction from the source electrode toward the drain electrode in an area where the source electrode and the first end portion overlap with each other. A second overlapping length is defined as a length along a direction from the drain electrode toward the source electrode in an area where the drain electrode and the second end portion overlap with each other. A sum of first and second overlapping lengths is between about 30% and about 99% of a total length of the etch stopper.

A first mask may be used in forming the etch stopper and a second mask may be used in forming the drain electrode. The second mask may include an opening having a length shorter than the length of a blocking portion of the first mask along the direction from source electrode toward the drain electrode.

The length of the opening may be between about 1% and about 70% of the length of the blocking portion.

The etch stopper may be formed by forming a first layer having an oxide on the substrate having the oxide semiconductor pattern formed on the substrate, forming a second layer on the substrate having the first layer formed on the substrate, and patterning the first and second layers. The second layer may have a material different from the first layer.

In a method for manufacturing a TFT, a gate electrode is formed on a substrate. An oxide semiconductor pattern is formed on the substrate having the gate electrode. An etch stopper having first and second layers is formed on the substrate having the oxide semiconductor pattern. The first layer has an oxide. The second layer is formed on the first layer and has a material different from the first layer. Source and drain electrodes are formed on the substrate having the etch stopper formed on the substrate. The source and drain electrodes are spaced apart from each other.

An overlay margin substantially equal to overlapping lengths between the etch stopper and the source electrode and between the etch stopper and the drain electrode is guaranteed, so that the change of the electrical characteristics of the TFT may be minimized even though the stopper is misaligned with the source and drain electrodes.

In addition, the etch stopper is formed with a double-layer, so that the change of the electrical characteristics of the TFT may be minimized even though the stopper is misaligned with the source and drain electrodes. Accordingly, the display substrate having the TFT may be have enhanced reliability.

### BRIEF DESCRIPTION OF THE DRAWINGS

The above and other features and advantages will become more apparent by describing in detail example embodiments thereof with reference to the accompanying drawings, in which:

FIG. 1 is a plan view partially illustrating a display substrate according an example embodiment;

FIG. 2 is a cross-sectional view taken along a line I-I′ in FIG. 2;

FIGS. 3A and 3B are cross-sectional views illustrating a method for manufacturing the display substrate in FIG. 2;

FIG. 4 is a cross-sectional view illustrating a display substrate according to another example embodiment;

FIG. 5 is an enlarged cross-sectional view illustrating a channel area to further illustrate an etch stopper in FIG. 4;

FIGS. 6A and 6B are cross-sectional views illustrating a method for manufacturing the display substrate in FIG. 4; and

FIG. 7 is a graph showing the relationship between gate voltage difference (ΔV) and overlapping length difference (ΔL) for samples according to the present example embodiments and samples according to comparative example embodiments.

### DETAILED DESCRIPTION OF THE INVENTION

Hereinafter, exemplary embodiments will be explained in detail with reference to the accompanying drawings.

FIG. 1 is a plan view partially illustrating a display substrate according an example embodiment.

Referring to FIG. 1, the display substrate 100 according to the present example embodiment includes a gate line GL, a data line DL, a thin-film transistor (TFT) TR that is a switching element, and a pixel electrode PE.

The gate line GL extends along a first direction D1 in the display substrate 100. The data line DL extends along a second direction D2 different from the first direction D1. For example, the second direction D2 may be substantially perpendicular to the first direction D1.

The TFT TR is electrically connected to the gate line GL, the data line DL and the pixel electrode PE. The TFT TR includes a gate electrode GE electrically connected to the gate line GL, a source electrode SE electrically connected to the data line DL, a drain electrode DE spaced apart from the source electrode SE, an oxide semiconductor pattern AP and an etch stopper ES. The source and drain electrodes SE and DE are spaced apart from each other along the first direction D1.

End portions of the oxide semiconductor pattern AP that are opposite to each other along the first direction D1 respectively overlap with the source electrode SE, on one side, and the drain electrode DE, on the other side. The oxide semiconductor pattern may include a single oxide such as, for example, a gallium oxide, an indium oxide, a tin oxide, a zinc oxide, etc, or a multi-element oxide such as, for example, a gallium-indium-zinc oxide (Ga₂O₃—In₂O₃—ZnO), an indium-gallium-tin oxide (In₂O₃—Ga₂O₃—SnO), an indium-zinc oxide (In₂O₃—Zn₂O₃), a zinc-aluminum oxide (Zn₂O₃—Al₂O₃), etc. The portion of the oxide semiconductor pattern AP exposed between the source and drain electrodes SE and DE may be defined as the channel of the TFT TR. In this case, a distance between the source and drain electrodes SE and DE in a direction substantially parallel to the first direction D1 is defined as a channel length CL of the TFT TR.

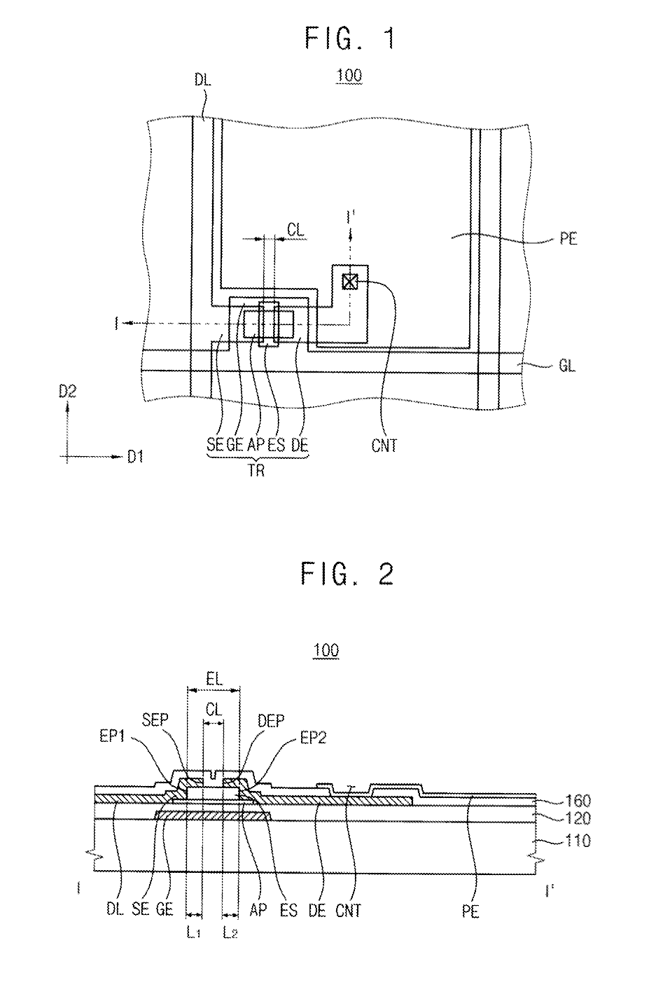

The etch stopper ES partially overlaps with each of the source and drain electrodes SE and DE. End portions of the etch stopper ES that are opposite to each other along the direction from the source electrode SE toward the drain electrode DE respectively overlap with the source SE, on one side, and the drain electrode DE on the other side. The etch stopper ES includes an oxide. For example, the etch stopper ES may include a silicon oxide. Alternatively, the etch stopper ES may include, for example, an oxide similar to an oxide semiconductor included in the oxide semiconductor pattern AP. The etch stopper ES is formed on the oxide semiconductor pattern AP to prevent the oxide semiconductor pattern AP from being damaged when the source and drain electrodes SE and DE are formed. In addition, the etch stopper ES prevents a passivation layer 160 (referring to FIG. 2), which is an insulating layer formed on the TFT TR, from directly contacting the oxide semiconductor pattern AP, which may prevent deterioration of the oxide semiconductor pattern AP.

The pixel electrode PE directly contacts the drain electrode DE through a contact hole CNT. The contact hole CNT is through the passivation layer 160 and partially exposes the drain electrode DE. Thus, the pixel electrode PE is electrically connected to the TFT TR.

FIG. 2 is a cross-sectional view taken along a line I-I′ in FIG. 2.

Referring to FIGS. 1 and 2, the gate electrode GE is formed on the substrate 110. The oxide semiconductor pattern AP, the etch stopper ES, the source electrode SE, the drain electrode DE and the pixel electrode PE are sequentially formed on the substrate 110 on which the gate electrode is formed.

The gate electrode GE may include, for example, a copper layer. The gate electrode GE may further include, for example, a titanium layer to increase adhesion between the copper layer and the substrate 110. For example, the copper layer may have a thickness of about 3000 Å and the titanium layer may have a thickness of about 200 Å, so that the gate electrode GE may have a thickness of about 3200 Å. The source and drain electrodes SE and DE may include a double-layer having, for example, the copper and titanium layers. In this case, the titanium layer may have a thickness of about 300 Å, and the copper layer may have a thickness of about 3000 Å.

The display substrate 100 may further include a gate insulating layer 120 formed between the gate electrode GE and the oxide semiconductor pattern AP. The gate insulating layer 120 may include, for example, silicon oxide (SiOx). Alternatively, the gate insulating layer 120 may include a double-layer having a first insulating layer and a second insulating layer. The first insulating layer includes, for example, silicon nitride (SiNx), and the second insulating layer is formed on the first insulating layer and includes, for example, silicon oxide (SiOx). Thus, the oxide semiconductor pattern AP may directly contact a layer including the silicon oxide. For example, the first insulating layer may have a thickness of about 4000 Å, and the second insulating layer may have a thickness of about 500 Å. The passivation layer 160 formed on the TFT TR may include, for example, silicon nitride.

The oxide semiconductor pattern AP is formed on the gate insulating layer 120 in an area where the gate electrode GE is formed. The area of the oxide semiconductor pattern AP (in a plan view, such as FIG. 1) is smaller than that of the gate electrode GE, and thus the gate electrode GE entirely overlaps the oxide semiconductor pattern AP (that is, no portion of the oxide semiconductor pattern AP extends beyond the edges of the gate electrode GE in a plan view, such as FIG. 1). In the present example embodiment, the oxide semiconductor pattern AP includes gallium-indium-zinc oxide, and has a thickness of about 400 Å.

An end portion SEP of the source electrode SE is disposed on the oxide semiconductor pattern AP. An opposite end portion of the source electrode SE is electrically connected to the data line DL. An end portion DEP of the drain electrode DE is disposed on the oxide semiconductor pattern AP. The end portion DEP of the drain electrode DE faces and is spaced apart from the end portion SEP of the source electrode SE. A distance between the end portion DEP and the end portion SEP is the channel length CL as defined above.

The etch stopper ES is disposed on the oxide semiconductor pattern AP. For example, the etch stopper ES is disposed in an area where the source and drain electrodes SE and DE are spaced apart from each other (i.e., the channel). A first end portion EP1 of the etch stopper ES is disposed between the oxide semiconductor pattern AP and the source electrode SE. A second end portion EP2 of the etch stopper ES is disposed between the oxide semiconductor pattern AP and the drain electrode DE. The first end portion EP1 and second end portion EP2 may be disposed opposite to each other along the first direction D1. A distance between the outer edge of the first end portion EP1 and the outer edge of the second end portion EP2 is defined as a total length EL of the etch stopper ES. A distance between both end portions of the etch stopper ES along the second direction D2 is defined as a total width of the etch stopper ES.

The total length EL of the etch stopper ES is larger than the channel length CL, and is smaller than a length of the oxide semiconductor pattern AP along the first direction D1. End portions of the oxide semiconductor pattern AP that extend beyond the first end portion EP1 and second end portion EP2 of the etch stopper ES directly contact the source and drain electrodes SE and DE, respectively. Thus, the source electrode SE and the drain electrode DE both directly contact the etch stopper ES and the oxide semiconductor pattern AP.

The first end portion EP1 overlaps with the end portion SEP of the source electrode SE by a first overlapping length L1. That is, the first overlapping length L1 is the distance along the etch stopper ES between the edge of the source electrode SE end portion SEP at the channel and the edge of first end portion EP1 of the etch stopper ES . The second end portion EP2 overlaps with the end portion DEP of the drain electrode DE by a second overlapping length L2. That is, the second overlapping length L2 is the distance along the etch stopper ES between the edge of the drain electrode end portion DEP at the channel and the edge of the second end portion EP2 of the etch stopper ES.

When the sum of the first overlapping length L1 and the second overlapping length L2 is less than about 30% of the total length EL, the oxide semiconductor pattern is easily damaged in the process of forming the source and drain electrodes SE and DE. In addition, when the sum of the first overlapping length L1 and the second overlapping length L2 is less than about 30% of the total length EL, and a difference between the first and second overlapping lengths L1 and L2 is more than 0 μm, an electric field is generated at the portion of the etch stopper that has the larger overlapping length and contacting one of the source and drain electrodes SE and DE respectively. As a result, an off current increases at the TFT TR, and electric characteristics of the TFT TR are changed. When the sum of the first and second overlapping lengths L1 and L2 is more than about 99% of the total length EL, the etch stopper ES is entirely covered by the source and drain electrodes SE and DE so that the channel of the TFT TR may not be substantially defined. Thus, in the exemplary embodiments the sum of the first and second overlapping lengths L1 and L2 is not more than about 99% of the total length EL. For example, the sum of the first and second overlapping lengths L1 and L2 may be not less than about 30% and not more than about 99% of the total length EL.

In the exemplary embodiments, the sum of the first and second overlapping lengths L1 and L2 is more than, for example, about 4 μm. If, for instance, the sum of the first and second overlapping lengths L1 and L2 is less than about 4 μm and the difference between the first and second overlapping lengths L1 and L2 is more than 0 μm, the electric field is generated at the portion of the etch stopper having the larger overlapping length and contacting one of the source and drain electrodes SE and DE respectively. As a result, the electric characteristics of the TFT TR may be changed. In addition, when the sum of the first and second overlapping lengths L1 and L2 is more than about, for example, 10 μm, an aperture ratio of the display substrate 100 decreases and display quality decreases. Thus, in the exemplary embodiments, the sum of the first and second overlapping lengths L1 and L2 is more than about 4 μm and not more than about 10 μm.

The total width of the etch stopper ES along the second direction D2 may be substantially the same as or larger than a width of the oxide semiconductor pattern AP along the second direction D2. The total width of the etch stopper ES is larger than the width of the oxide semiconductor pattern AP along the second direction D2 to cover each of both end portions of the oxide semiconductor pattern AP facing each other along the second direction D2. Thus, the oxide semiconductor pattern AP may be protected.

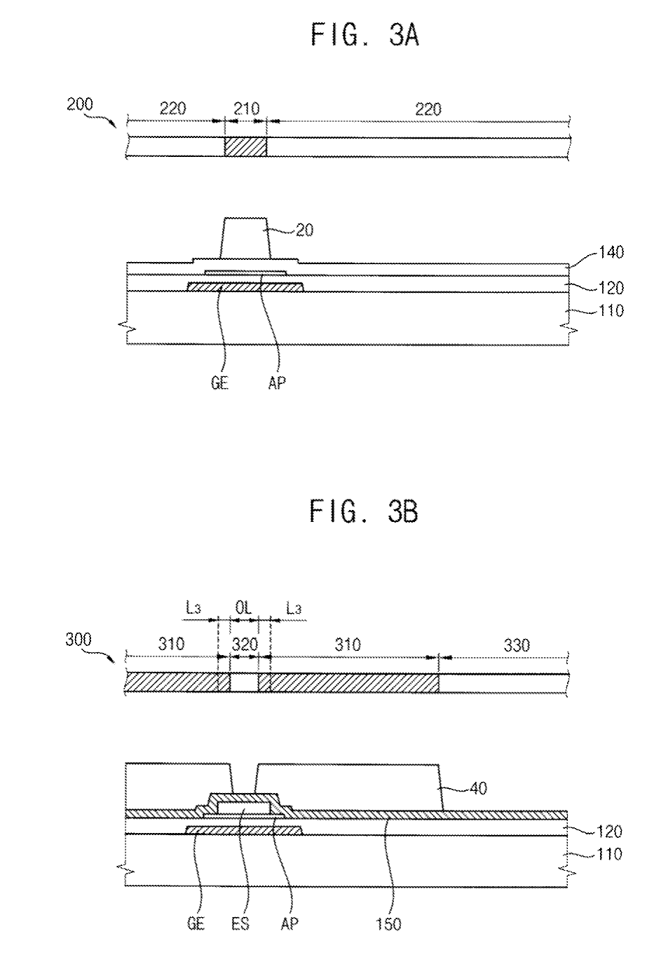

FIGS. 3A and 3B are cross-sectional views illustrating a method for manufacturing the display substrate in FIG. 2.

Referring to FIG. 3A, the gate line GL and the gate electrode GE are formed on the substrate 110 using a first mask (not shown). The gate insulating layer 120 is formed on the substrate 110 having the gate line GL and the gate electrode GE. The oxide semiconductor pattern AP is formed on the substrate 110 having the gate insulating layer 120 using a second mask (not shown).

Then, an insulating layer 140 is formed on the substrate 110 having the oxide semiconductor pattern AP, and a first photoresist pattern 20 is formed on the insulating layer 140 using a third mask 200. The insulating layer 140 may include, for example, silicon oxide or silicon nitride. The third mask 200 includes, for example, a light blocking portion 210 and a transmissive portion 220. The light blocking portion is disposed over a first area where the etch stopper ES is formed, and the transmissive portion 220 is disposed over a second area that does not include the first area. In the third mask 200, the positions of the light blocking portion 200 and the transmissive portion 220 may be reversed according to characteristics of the photoresist pattern 20. A length of the light blocking portion 210 along the first direction D1 may be determined considering the total length EL of the etch stopper ES. The insulating layer 140 is etched using the first photoresist pattern 20 as an etch stopping layer, so that the insulating layer 140 exposed by the first photoresist pattern 20 is removed, and the insulating layer disposed under the first photoresist pattern 20 remains to be the etch stopper ES.

Referring to FIG. 3B, a data metal layer 150 is formed on the substrate on which the etch stopper ES is formed, and a photoresist layer is formed on the data metal layer 150. A fourth mask 300 is disposed over the substrate on which the photoresist layer is formed, and then the photoresist layer is irradiated with light from above the fourth mask 300, and the photoresist layer is developed, to become a second photoresist pattern 40.

The fourth mask 300 includes a blocking portion 310, a first opening 320 and a second opening 330. The first opening 320 may be disposed over an area where the source and drain electrodes SE and DE are spaced apart from each other. The second opening 330 may be disposed over an area where a pixel and the gate line GL of the display substrate 100 are formed. The data metal layer 150 formed in an area corresponding to the first and second opening 320 and 330 is exposed by the second photoresist pattern 140 and is removed via an etching process. An opening length OL is defined as a length of the first opening 320 along the first direction D1. The opening length OL is shorter than the total length EL of the etch stopper ES. The opening length OL of the first opening 320 may be between about 1% and about 70% of the total length EL of the etch stopper ES. When the fourth mask 300 overlaps with the third mask 200, the blocking portion 310 adjacent to the first opening 320 overlaps with the light blocking portion 210 on each side of the light blocking portion 210 by a third overlapping length L3. The first opening 320 is enclosed by the blocking portion 310, so that the overlapping length between the light blocking portion 210 and the blocking portion 310 adjacent to the first opening 320 is substantially twice as large as the third overlapping length L3. The third overlapping length L3 is a half of the sum of the first and second overlapping lengths L1 and L2. The fourth mask 300 is formed to have the third overlapping length L3 to be the half of the sum of the first and second overlapping lengths L1 and L2, and to have the opening length OL to be between about 1% and about 70% of the total length EL of the etch stopper ES. Thus, even if the first and second overlapping lengths L1 and L2 are different from each other, which may be caused by aberrant positions of the source and drain electrodes SE and DE due to a misalignment between the fourth mask 300 and the substrate 110, any resulting change of the electric characteristics of the TFT TR may be minimized.

The data metal layer 150 is patterned using the second photoresist pattern 40 as an etch stopping layer. Thus, the source and drain electrodes SE and DE are formed as illustrated in FIGS. 1 and 2. After forming the source and drain electrodes SE and DE, the passivation layer 160 is formed. A contact hole CNT is then formed through the passivation layer 160 using a fifth mask (not shown). Then, the pixel electrode PE is formed on the substrate 110 on which the passivation layer 160 having the contact hole CNT is formed. Thus, display substrate 110 according to the present example embodiments is manufactured.

According to the present example embodiments, the sum of the first and second overlapping lengths L1 and L2 is not less than about 30% and not more than about 99% of the total length EL of the etch stopper ES, so that an overlay margin between the etch stopper ES and the source electrode SE, and an overlay margin between the etch stopper ES and the drain electrode DE, may be guaranteed. Thus, even though the first and second overlapping lengths L1 and L2 may be different from each other due to the misalignment between the etch stopper ES and each of the source and drain electrodes SE and DE, any resulting change of the electric characteristics of the TFT TR may be minimized.

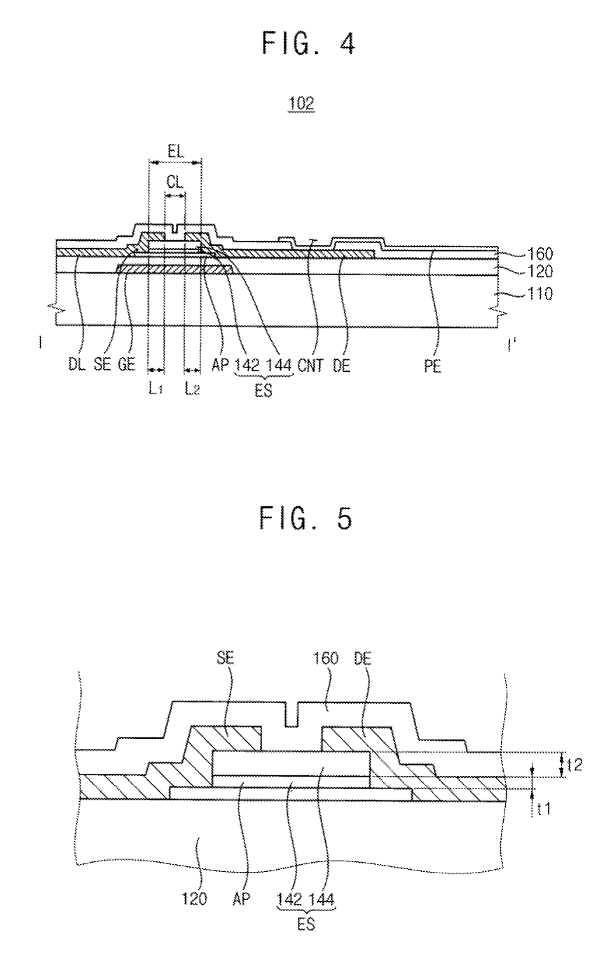

FIG. 4 is a cross-sectional view illustrating a display substrate according to another example embodiment.

The display substrate according to the present example embodiment has substantially same structure in a plan view as the display substrate according to the previous example embodiment in FIG. 1, and thus the structure in the plan view of the display substrate according to the present example embodiment will be omitted. In addition, the display substrate according to the present example embodiment is substantially same as the display substrate according to the previous example embodiment with the exception of an etch stopper, and thus repetitive explanation will be omitted.

Referring to FIG. 4, the display substrate 102 according to the present example embodiment includes a gate electrode GE, a gate insulating layer 120, an oxide semiconductor pattern AP, an etch stopper ES, a source electrode SE, a drain electrode DE, a passivation layer 160 and a pixel electrode PE, which are formed on a substrate 110.

The etch stopper ES includes a first layer 142 formed on the oxide semiconductor pattern AP and a second layer 144 formed on the first layer 142. The first and second layers 142 and 144 respectively include materials that are different from each other. The first layer 142 includes, for example, an oxide. The first layer 142 may include, for example, a silicon oxide. Alternatively, the first layer 142 may include, for example, an oxide similar to an oxide semiconductor included in the oxide semiconductor pattern. For example, the first layer 142 may include a single oxide such as a gallium oxide, an indium oxide, a tin oxide, a zinc oxide, etc, or a multi-element oxide such as a gallium-indium-zinc oxide (Ga₂O₃—In₂O₃—ZnO), an indium-gallium-tin oxide (In₂O₃—Ga₂O₃—SnO), an indium-zinc oxide (In₂O₃—Zn₂O₃), a zinc-aluminum oxide (Zn₂O₃—Al₂O₃), etc.

The second layer 144 may include, for example, a nitride. When the second layer 144 includes an oxide like the first layer 142, forming the etch stopper ES by etching the first and second layers 142 and 144 requires more time than forming the etch stopper ES when the second layer 144 includes a nitride. Thus, the second layer 144 includes a material that is different from the first layer 142.

The relations between the etch stopper ES and the source electrode SE, and between the etch stopper ES and the drain electrode DE are substantially the same as explained above with reference to FIG. 2. For example, the sum of the first overlapping length L1 between the etch stopper ES and the source electrode SE and the second overlapping length L2 between the etch stopper ES and the drain electrode DE may be not more than about 99% of the total length EL of the etch stopper ES or more than about 4 μm.

However, according to the present example embodiment, the etch stopper ES includes the first and second layers 142 and 144, to help ensure that the maximum thickness of the etch stopper ES is at a predetermined value, and to decrease the manufacturing time for the etch stopper ES. Thus, even if, for instance, the first and second overlapping lengths L1 and L2 are different from each other due to the misalignment between the etch stopper ES and each of the source and drain electrodes SE and DE, any resulting change of the electric characteristics of the TFT TR may be minimized.

Hereinafter, the first and second layers L1 and L2 142 and 144 of the etch stopper ES of FIG. 4 will be detailed referring to FIG. 5, which is an enlarged cross-sectional view illustrating a channel area.

Referring to FIG. 5, when the thickness of the etch stopper ES is less than about 600 Å, the oxide semiconductor pattern AP is easily damaged in the process of forming the source and drain electrodes SE and DE. In addition, when the thickness of the etch stopper ES is less than about 600 Å, and with misalignment between the etch stopper ES and each of the source and drain electrodes SE and DE, the etch stopper ES may partially function as a channel. Thus, the electric characteristics of the TFT TR may be changed. When the thickness of the etch stopper ES is more than about 3000 Å, a relatively longer time is required to manufacture the etch stopper ES, which can decrease productivity. Thus, the thickness of the etch stopper ES is, for example, between about 600 Å and about 3000 Å. When the thickness of the etch stopper ES is between about 600 Å and about 3000 Å, even if the first and second overlapping lengths L1 and L2 are different from each other due to a misalignment between the etch stopper ES and each of the source and drain electrodes DE and SE, any resulting change in the electric characteristics of the TFT TR may be minimized. As the thickness of the etch stopper ES increases, any such change in the electric characteristics due to the misalignment are increasingly minimized. Thus, the thickness of the etch stopper ES may be, for example, between about 2000 Å and about 3500 Å, considering characteristics of the first and second layers 142 and 144 and the manufacturing process of the etch stopper ES.

The first layer 142 of the etch stopper ES directly contacts the oxide semiconductor pattern AP. When a first thickness t1 of the first layer 142 is less than about 300 Å, the first layer 142 may not sufficiently prevent the oxide semiconductor pattern AP from being chemically deteriorated by the second layer 144. In addition, when the first thickness t1 of the first layer 142 is more than about 1000 Å, the manufacturing time required to form the etch stopper is increased, and uniformity of etching is decreased. As a result, the reliability and productivity of the manufacturing process may be decreased. Thus, the first thickness t1 is between about 300 Å and about 1000 Å.

When a second thickness t2 of the second layer 144 is less than about 300 Å, the thickness of the t1 of the first layer 142 must be increased to ensure a predetermined thickness of the etch stopper ES. As a result, the reliability and the productivity of the manufacturing process may be decreased. In addition, when the second thickness t2 of the second layer 144 is less than about 300 Å, optimizing total thickness of the etch stopper ES is difficult, and thus the oxide semiconductor pattern AP may be easily damaged by the etch stopper ES. When, on the other hand, the second thickness t2 of the second layer 144 is more than about 2000 Å, the total thickness of the etch stopper ES is excessively increased, which increases a stepped portion between the etch stopper ES and the gate insulating layer 120. As a result, a disconnection can easily occur due to the misalignment in forming the source and drain electrodes SE and DE. Thus, the second thickness t2 is between about 300 Å and about 2000 Å.

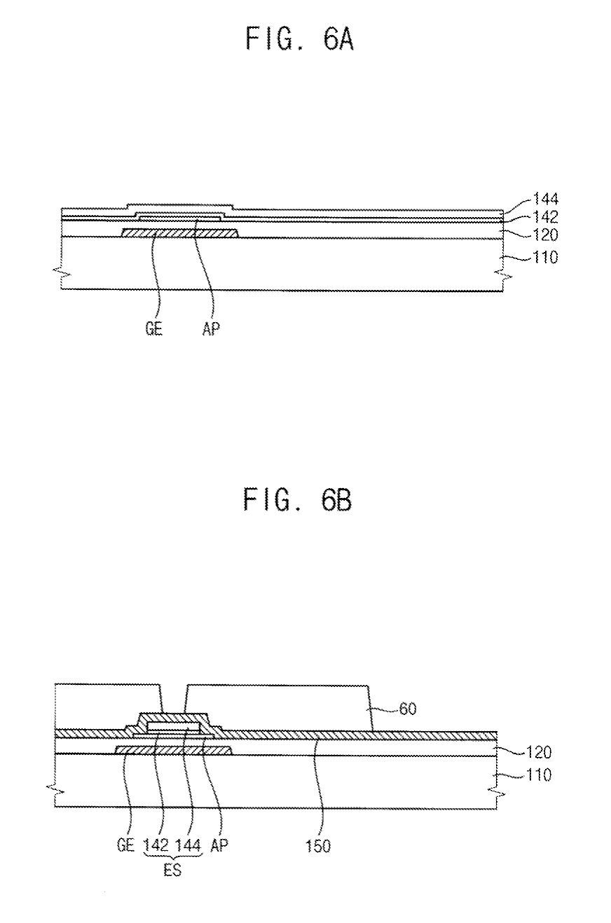

FIGS. 6A and 6B are cross-sectional views illustrating a method for manufacturing the display substrate in FIG. 4. Hereinafter, the method for manufacturing the display substrate 102 in FIG. 4 will be explained referring to FIGS. 4, 5, 6A and 6B.

Referring to FIG. 6A, the gate electrode GE is formed on the substrate 110 using a first mask (not shown). Then, the gate insulating layer 120 and the semiconductor layer are formed on the substrate 110 on which the gate electrode GE is formed.

The semiconductor layer is patterned using a second mask (not shown) to form the oxide semiconductor pattern AP. The first and second layers 142 and 144 are sequentially formed on the substrate 110 on which the oxide semiconductor pattern AP is formed. For example, the first layer 142 may include the silicon oxide, and the second layer 144 may include the silicon nitride.

Then, the first and second layers 142 and 144 are patterned using a third mask (not shown) to form the etch stopper ES. The remaining first and second layers 142 and 144 define the etch stopper ES, which is in an area in which the gate electrode GE is formed.

Referring to FIG. 6B, the data metal layer 150 is formed on the substrate 110 on which the etch stopper ES is formed, and the photoresist layer is formed on the data metal layer 150. A fourth mask (not shown) is disposed over the substrate 110 on which the photoresist layer is formed. Then the photoresist layer is irradiated with light from above the fourth mask, and the photoresist layer is developed to be a photoresist pattern 60. The fourth mask is substantially same as the mask illustrated in FIG. 3B. The fourth mask is used, so that even if the source and drain electrodes SE and DE are abnormally positioned due to the misalignment between the fourth mask and the substrate 110, any resulting change of the electric characteristics of the TFT TR may be minimized.

Next, the data metal layer 150 is patterned using the photoresist pattern 60 as the etch stopping layer. Thus, the source and drain electrodes SE and DE are formed as illustrated in FIGS. 4 and 5. After forming the source and drain electrodes SE and DE, the passivation layer 160 is formed, and the contact hole CNT is formed through the passivation layer 160 using a fifth mask (not shown). Then, the pixel electrode PE is formed on the substrate 110 on which the passivation layer 160 having the contact hole CNT is formed. Accordingly, the display substrate 102 as illustrated in FIGS. 4 and 5 is manufactured.

According to the present example embodiment, the etch stopper ES is formed as a double-layer, and any change of the electric characteristics of the TFT TR may be minimized even if the first and second overlapping lengths L1 and L2 are different from each other due to the misalignment between the etch stopper ES and each of the source and drain electrodes SE.

Hereinafter, the effect of a difference in the length of overlap (between an etch stopper and source electrode and drain electrode) and a gate voltage differences is illustrated by comparing a sample according to the present example embodiment and a sample according comparative example. In the sample according to the present example embodiment, the sum of the first and second overlapping lengths is 8 μm. In the sample according to the comparative example the sum of the first and second overlapping lengths is 4 μm.

Manufacturing of Samples According the Present Example Embodiment

The samples according to the present example embodiment were manufactured so that each of the TFTs had a channel length of about 4 μm, the total length of the etch stopper was about 12 μm, and the width of the etch stopper was about 25 μm, and the following conditions as shown in Table 1 were satisfied:

TABLE 1

| | Overlapping | Overlapping | |
|---|---|---|---|
| | length (L1) | length (L2) | |
| | between etch | between etch | |
| | stopper and | stopper and drain | ΔL |
| | source electrode [μm] | electrode [μm] | (=L2 − L1) |
| Sample 1 | 5.25 | 2.75 | −2.50 |
| Sample 2 | 4.93 | 3.07 | −1.86 |
| Sample 3 | 4.80 | 3.20 | −1.60 |
| Sample 4 | 4.77 | 3.23 | −1.55 |
| Sample 5 | 4.45 | 3.55 | −0.90 |
| Sample 6 | 4.37 | 3.63 | −0.75 |
| Sample 7 | 4.30 | 3.70 | −0.60 |
| Sample 8 | 4.00 | 4.00 | 0.00 |
| Sample 9 | 3.80 | 4.20 | 0.40 |
| Sample 10 | 3.70 | 4.30 | 0.60 |
| Sample 11 | 3.62 | 4.38 | 0.75 |
| Sample 12 | 3.45 | 4.55 | 1.10 |
| Sample 13 | 3.20 | 4.80 | 1.60 |

Manufacturing the Samples According to the Comparative Examples

The samples according to comparative examples were manufactured with the following conditions as shown in Table 2.

TABLE 2

| | | | Overlapping length | Overlapping length | |
|---|---|---|---|---|---|
| | Width of | | (L1) between etch | (L2) between etch | |
| | etch | Channel | stopper and source | stopper and drain | |
| | stopper | length | electrode [μm] | electrode [μm] | ΔL (=L2 − L1) |
| Comparative | 10 | 6 | 3.25 | 0.75 | −2.50 |
| sample 1 | | | | | |
| Comparative | 10 | 6 | 2.93 | 1.07 | −1.86 |
| sample 2 | | | | | |
| Comparative | 10 | 6 | 2.80 | 1.20 | −1.60 |
| sample 3 | | | | | |
| Comparative | 10 | 6 | 2.77 | 1.23 | −1.55 |
| sample 4 | | | | | |
| Comparative | 10 | 6 | 2.45 | 1.55 | −0.90 |
| sample 5 | | | | | |
| Comparative | 10 | 6 | 2.37 | 1.63 | −0.75 |
| sample 6 | | | | | |
| Comparative | 10 | 6 | 2.30 | 1.70 | −0.60 |
| sample 7 | | | | | |
| Comparative | 10 | 6 | 2.00 | 2.00 | 0.00 |
| sample 8 | | | | | |
| Comparative | 10 | 6 | 1.80 | 2.20 | 0.40 |
| sample 9 | | | | | |
| Comparative | 10 | 6 | 1.70 | 2.30 | 0.60 |
| sample 10 | | | | | |
| Comparative | 10 | 6 | 1.62 | 2.38 | 0.75 |
| sample 11 | | | | | |
| Comparative | 10 | 6 | 1.45 | 2.55 | 1.10 |
| sample 12 | | | | | |
| Comparative | 10 | 6 | 1.20 | 2.80 | 1.60 |
| sample 13 | | | | | |
| Comparative | 15 | 11 | 3.25 | 0.75 | −2.50 |
| sample 14 | | | | | |
| Comparative | 15 | 11 | 2.93 | 1.07 | −1.86 |
| sample 15 | | | | | |
| Comparative | 15 | 11 | 2.80 | 1.20 | −1.60 |
| sample 16 | | | | | |
| Comparative | 15 | 11 | 2.77 | 1.23 | −1.55 |
| sample 17 | | | | | |
| Comparative | 15 | 11 | 2.45 | 1.55 | −0.90 |
| sample 18 | | | | | |
| Comparative | 15 | 11 | 2.37 | 1.63 | −0.75 |
| sample 19 | | | | | |
| Comparative | 15 | 11 | 2.30 | 1.70 | −0.60 |
| sample 20 | | | | | |
| Comparative | 15 | 11 | 2.00 | 2.00 | 0.00 |
| sample 21 | | | | | |
| Comparative | 15 | 11 | 1.80 | 2.20 | 0.40 |
| sample 22 | | | | | |
| Comparative | 15 | 11 | 1.70 | 2.30 | 0.60 |
| sample 23 | | | | | |
| Comparative | 15 | 11 | 1.62 | 2.38 | 0.75 |
| sample 24 | | | | | |
| Comparative | 15 | 11 | 1.45 | 2.55 | 1.10 |
| sample 25 | | | | | |
| Comparative | 15 | 11 | 1.20 | 2.80 | 1.60 |
| sample 26 | | | | | |

Evaluation of the Characteristics of the TFT

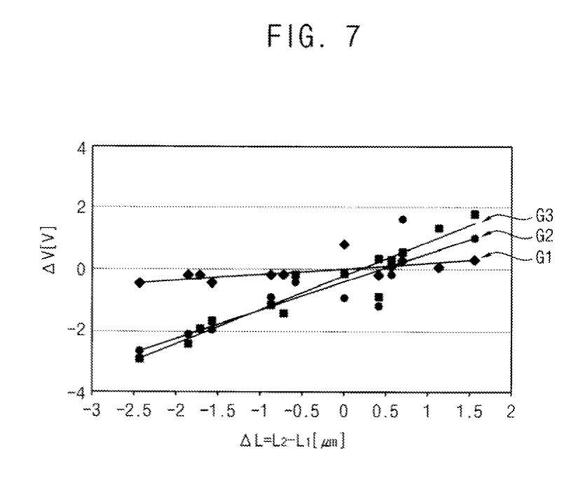

In each of Samples 1 to 13 and Comparative samples 1 to 26, a forward gate on voltage of the TFT was measured at about 1 nA, when about 0V and about 10V were respectively applied to the source and drain electrodes. In addition, a reverse gate on voltage of the TFT was measured at about 1 nA, when about 0V and about 10V were respectively applied to the source and drain electrodes. A gate voltage difference was calculated by subtracting the forward gate on voltage from the reverse gate on voltage, and then the gate voltage difference ΔV according to the overlapping length difference ΔL was graphed, as illustrated in FIG. 7. The overlapping length difference ΔL is the difference between the overlap of the etch stopper and the source electrode and the overlap of the etch stopper and the drain electrode.

As the gate voltage difference ΔV is close to about 0V, the electric characteristics of the TFT are not changed. As the gate voltage difference ΔV becomes lager or smaller than about 0V, the electrical characteristics of the TFT are changed due to the overlapping length difference ΔL.

The graph in FIG. 7 shows the relationship between overlapping length differences V and gate voltage differences for the samples according to the present example embodiment and the samples according to the comparative example to provide comparison between the samples according to the present example embodiments with the samples according to the comparative example embodiments.

In FIG. 7, the X axis indicates the overlapping length difference ΔL [μm] obtained by subtracting the first overlapping length L1 from the second overlapping length L2, and Y axis indicates the gate voltage difference ΔV[V] obtained by subtracting the forward gate on voltage from the reverse gate on voltage. ΔL and ΔV of each of Samples 1 to 13 according to the present example embodiment were indicated as (X, Y) coordinates. The straight line connecting each of the coordinates of Samples 1 to 13 is first straight line G1, the straight line connecting each of the coordinates of Comparative samples 1 to 13 is second straight line G2, and the straight line connecting each of the coordinates of Comparative samples 14 to 26 is third straight line G3.

Referring to FIG. 7, the slope of the first straight line G1 is about 0.1769, the slope of the second straight line is about 0.9074, and the slope of the third straight line is about 1.0984.

Comparing the slopes of the first to third straight lines G1, G2 and G3, the slope of the first straight line G1 is the smallest, so that the gate voltage difference ΔV according to the overlapping length difference ΔL is also the smallest relative to G2 and G3. For example, when the sum of the overlapping length L1 between the etch stopper and the source electrode and the overlapping length L2 between the etch stopper and the drain electrode is about 8 μm, even if the overlapping length difference is not about 0 μm, the gate voltage difference ΔV according to the overlapping length difference ΔL is relatively small compared to a case in which the sum of the overlapping lengths is about 4 μm.

According to the present exemplary embodiments, an overlay margin substantially equal to overlapping lengths between the etch stopper and the source electrode and between the etch stopper and the drain electrode is guaranteed, so that any changes in the electric characteristics of the TFT that may result from an etch stopper being misaligned with the source and drain electrodes may be minimized.

In addition, the etch stopper is formed with a double-layer, so that any changes in the electric characteristics of the TFT may be minimized even if the stopper is misaligned with the source and drain electrodes. Accordingly, the display substrate having the TFT may have enhanced reliability.

The foregoing is illustrative of the present invention and is not to be construed as limiting thereof. Although example embodiments have been described, those persons of ordinary skill in the relevant art will readily appreciate that many modifications are possible in the example embodiments without materially departing from the novel teachings and advantages of the present disclosure. Therefore, it is to be understood that the foregoing is illustrative of the present invention and is not to be construed as limited to the specific example embodiments disclosed, and that modifications to the disclosed example embodiments, as well as other example embodiments, are intended to be included within the scope of the disclosure including the appended claims.

What is claimed is:

1. A thin-film transistor (TFT) comprising:
a gate electrode formed on a substrate;
an oxide semiconductor pattern disposed in an area overlapping with the gate electrode;
a source electrode partially disposed on the oxide semiconductor pattern;
a drain electrode spaced apart from the source electrode, facing the source electrode and partially disposed on the oxide semiconductor pattern; and
an etch stopper having first and second end portions, the first end portion being disposed between the oxide semiconductor pattern and the source electrode, the second end portion being disposed between the oxide semiconductor pattern and the drain electrode, wherein a first overlapping length is defined as a length along a direction from the source electrode toward the drain electrode in an area where the source electrode and the first end portion overlap with each other, a second overlapping length is defined as a length along a direction from the drain electrode toward the source electrode in an area where the drain electrode and the second end portion overlap with each other, and a sum of first and second overlapping length is between about 30% and about 99% of a total length of the etch stopper between an outer edge of the first end portion and an outer edge of the second end portion.

2. The TFT of claim 1, wherein the sum of the first and second overlapping lengths is more than about 4 μm and not more than 10 μm.

3. The TFT of claim 2, wherein the etch stopper comprises:
a first layer directly contacting the oxide semiconductor pattern; and
a second layer formed on the first layer, directly contacting the source and drain electrodes, and having a material different from the first layer.

4. The TFT of claim 3, wherein the first layer includes a silicon oxide and the second layer includes a silicon nitride.

5. The TFT of claim 4, wherein the first layer includes a metallic oxide and the second layer includes a metallic nitride.

6. The TFT of claim 2, wherein the sum of the first and second overlapping length is about 8 μm.

7. The TFT of claim 6, wherein total length of the etch stopper is about 12 μm.

8. The TFT of claim 1, wherein the etch stopper comprises:
a first layer directly contacting the oxide semiconductor pattern; and
a second layer formed on the first layer, directly contacting the source and drain electrodes, and having a material different from the first layer.

9. The TFT of claim 8, wherein the first layer includes a silicon oxide and the second layer includes a silicon nitride

10. The TFT of claim 8, wherein the first layer includes a metallic oxide and the second layer includes a metallic nitride.

11. The TFT of claim 8, wherein the first layer has a thickness between about 300 Å and about 1000 Å, and the second layer has a thickness between about 300 Å and about 2000 Å.

12. A TFT comprising:
a gate electrode formed on a substrate;
an oxide semiconductor pattern disposed in an area overlapping with the gate electrode;
an etch stopper comprising first and second layers, the first layer being formed on the oxide semiconductor pattern, the second layer being formed on the first layer and having a material different from the first layer;
a source electrode overlapping a first end portion of the etch stopper; and
a drain electrode overlapping a second end portion of the etch stopper.

13. The TFT of claim 12, wherein the first layer includes a metallic oxide.

14. The TFT of claim 12, wherein the first layer includes a silicon oxide and the second layer includes a silicon nitride.

15. The TFT of claim 12, wherein the first layer has a thickness between about 300 Å and about 1000 Å, and the second layer has a thickness between about 300 Å and about 2000 Å.

16. A method for manufacturing a TFT, the method comprising:
forming a gate electrode on a substrate;
forming an oxide semiconductor pattern on the substrate having the gate electrode;
forming an etch stopper on the substrate having the oxide semiconductor pattern; and
forming source and drain electrodes on the substrate having the etch stopper, the source and drain electrodes being spaced apart from each other, wherein a first overlapping length is defined as a length along a direction from the source electrode toward the drain electrode in an area where the source electrode and the first end portion overlap with each other, a second overlapping length is defined as a length along a direction from the drain electrode toward the source electrode in an area where the drain electrode and the second end portion overlap with each other, and a sum of first and second overlapping length being between about 30% and about 99% of a total length of the etch stopper between an outer edge of the first end portion and an outer edge of the second end portion.

17. The method of claim 16, wherein a first mask is used in forming the etch stopper and a second mask is used in forming the drain electrode, and
the second mask includes an opening having a length shorter than the length of a blocking portion of the first mask along the direction from source electrode toward the drain electrode.

18. The method of claim 17, wherein the length of the opening is between about 1% and about 70% of the length of the blocking portion.

19. The method of claim 16, wherein the etch stopper is formed by:
forming a first layer having an oxide on the substrate;
forming a second layer on the substrate having the first layer formed on the substrate, the second layer having a material different from the first layer; and
patterning the first and second layers to form the etch stopper.

20. A method for manufacturing a TFT, the method comprising:
forming a gate electrode on a substrate;
forming an oxide semiconductor pattern on the substrate having the gate electrode ;
forming an etch stopper having first and second layers on the substrate having the oxide semiconductor pattern, the first layer having an oxide, the second layer being formed on the first layer and having a material different from the first layer; and
forming source and drain electrodes on the substrate having the etch stopper, the source and drain electrodes being spaced apart from each other.

21. The method of claim 20, wherein the first layer includes a silicon oxide and the second layer includes a silicon nitride.
